(19) United States
(12) Patent Application Publication
(10) Pub. No.: US 2025/0069937 A1
(43) Pub. Date: Feb. 27, 2025

(54) SUBSTRATE TRANSFER APPARATUS AND SUBSTRATE TRANSFER METHOD

(71) Applicant: Tokyo Electron Limited, Tokyo (JP)

(72) Inventor: Toshichika TAKEI, Kumamoto (JP)

(21) Appl. No.: 18/808,358

(22) Filed: Aug. 19, 2024

(30) Foreign Application Priority Data
Aug. 21, 2023 (JP) 2023-133872

(51) Int. Cl. H01L 21/683; B65G 47/91; G05B 19/4155; H01L 21/687

(52) U.S. Cl. CPC H01L 21/6838; B65G 47/91; G05B 19/4155; H01L 21/68707; G05B 2219/50387

(57) ABSTRACT

A substrate transfer apparatus includes a transfer arm which includes a base portion; at least one arm portion connected to the base portion to extend from the base portion; a plurality of adsorption units provided in the at least one arm portion and each including a suction port that adsorbs a peripheral edge of a back surface of the substrate; and a plurality of suction passages provided in the at least one arm portion. The adsorption units include a first adsorption unit group including a first adsorption unit and a second adsorption unit; and a second adsorption unit group including a third adsorption unit and a fourth adsorption unit. The suction passages include a first suction passage connected to the suction ports of the first and second adsorption units, and a second suction passage connected to the suction ports of the third and fourth adsorption units.

### CROSS-REFERENCE TO RELATED APPLICATIONS

This application is based on and claims priority from Japanese Patent Application No. 2023-133872 filed on Aug. 21, 2023, with the Japan Patent Office, the disclosure of which is incorporated herein in its entirety by reference.

### TECHNICAL FIELD

The present disclosure relates to a substrate transfer apparatus and a substrate transfer method.

### BACKGROUND

Japanese Patent Laid-Open Publication No. 2017-183704 discloses a substrate transfer apparatus provided in a substrate processing apparatus that processes substrates such as semiconductor wafers. The substrate transfer apparatus is configured to move between different processing modules, for example, to transfer substrates from one processing module to another processing module in the substrate processing apparatus. For example, the substrate transfer apparatus is configured to move between a carrier accommodating a plurality of substrates and a processing module, to pick up a substrate from the carrier and transfer the substrate to the processing module, or to return the substrate that has been processed in the processing module to the carrier.

### SUMMARY

According to an aspect of the present disclosure, a substrate transfer apparatus includes a transfer arm, a drive unit that moves the transfer arm; and a control unit that controls the drive unit. The transfer arm includes a base portion, at least one arm portion connected to the base portion to extend from the base portion and surrounding an outer circumference of a substrate, a plurality of adsorption units provided in the at least one arm portion and each including a suction port that adsorbs a peripheral edge of a back surface of the substrate, and a plurality of suction passages provided in the at least one arm portion. The plurality of adsorption units include a first adsorption unit group including a first adsorption unit and a second adsorption unit; and a second adsorption unit group including a third adsorption unit and a fourth adsorption unit. The plurality of suction passages include a first suction passage connected to the suction ports of the first adsorption unit and the second adsorption unit, and a second suction passage connected to the suction ports of the third adsorption unit and the fourth adsorption unit.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic plan view of a substrate processing system.

FIG. 2 is a schematic side view of the substrate processing system.

FIG. 3 is a schematic perspective view illustrating an example of a processing station.

FIG. 4 is a perspective view illustrating an example of a transfer arm.

FIG. 5 is a plan view illustrating an upper surface of the transfer arm illustrated in FIG. 4.

FIG. 6 is a plan view illustrating a lower surface of the transfer arm illustrated in FIG. 4.

FIG. 7 is a perspective view illustrating an adsorption pad included in the transfer arm illustrated in FIG. 4.

FIG. 8 is a cross-sectional view illustrating the adsorption pad of FIG. 7.

FIG. 9 is a block diagram illustrating a main part of the substrate processing system.

FIG. 10 is a schematic diagram illustrating a hardware configuration of a controller.

FIG. 11 is a flowchart illustrating an order of transferring a substrate by a substrate transfer apparatus.

FIG. 12 is a schematic plan view illustrating another example of a processing station.

FIG. 13 is a schematic side view of the processing station illustrated in FIG. 12.

FIG. 14 is a perspective view illustrating a support of the substrate transfer apparatus provided in the processing station illustrated in FIG. 12.

FIG. 15 is a plan view illustrating another example of a transfer arm.

FIG. 16 is a plan view illustrating still another example of a transfer arm.

FIG. 17 is a plan view illustrating still another example of a transfer arm.

FIG. 18 is a plan view illustrating yet another example of a transfer arm.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

In the respective drawings, the same components may be denoted by the same reference numerals, and overlapping descriptions thereof may be omitted. In addition, references herein to the top, the bottom, the right, and the left of the drawings are intended to refer to directions of the symbols in the drawings. Some of the drawings illustrate an orthogonal coordinate system defined by an X-axis, a Y-axis, and a Z-axis. In the specification, the X-axis and the Y-axis correspond to a horizontal direction and the Z-axis corresponds to a vertical direction.

### [Substrate Processing System]

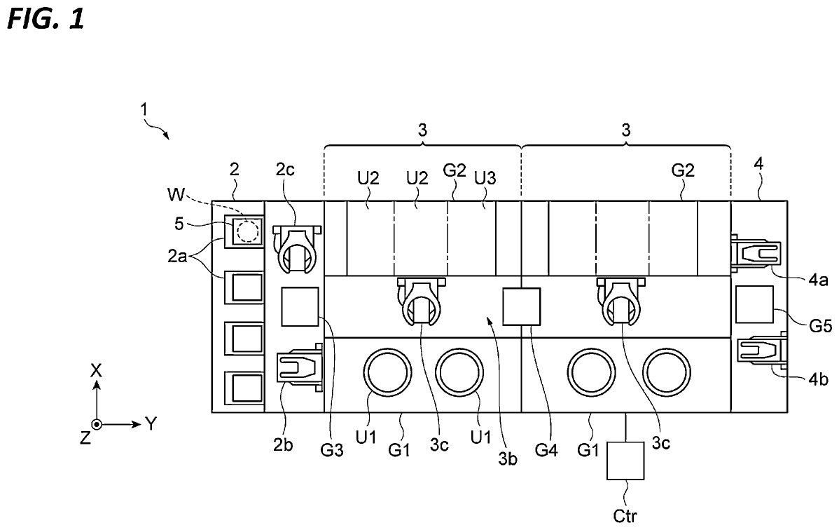

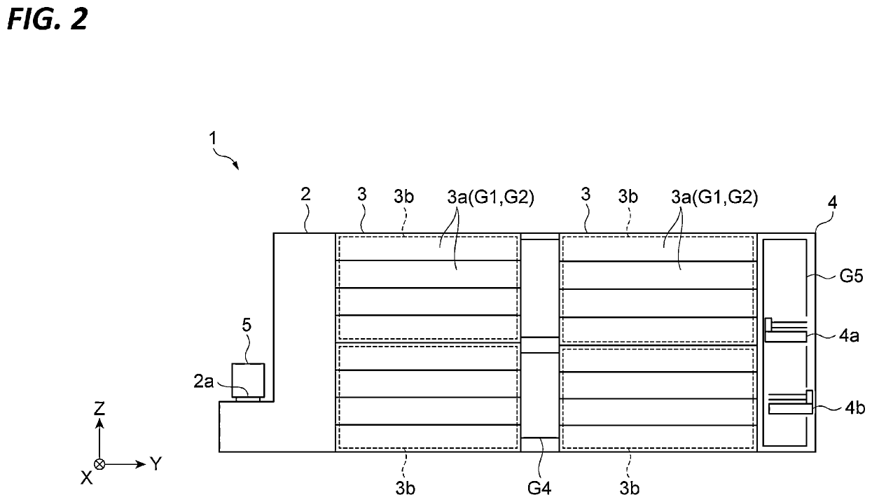

First, a substrate processing system 1 (substrate processing apparatus) that processes a substrate W is described with reference to FIGS. 1 and 2. The substrate processing system 1 may be configured to perform various kinds of processing such as, for example, a photolithography processing, a cleaning processing, and an etching processing, on the substrate W. The photolithography processing may include, for example, a processing of forming a photosensitive thin film (e.g., a resist film) on a surface of the substrate W, and a processing of developing the photosensitive thin film after exposure.

The substrate W may have a circular disc shape, or may have a plate shape other than a circular shape, such as a polygonal shape. The substrate W may have a cut-out portion from which a part of the substrate W is cut-away. The cut-out portion may be, for example, a notch (a groove in a U-shape or a V-shape) or may be a linear portion extending linearly (a so-called orientation flat). Examples of the substrate W may include a semiconductor substrate (silicon wafer), a glass substrate, a mask substrate, a flat panel display (FPD), and various other substrates.

The substrate processing system 1 includes a cassette station 2 where a cassette 5 capable of accommodating a plurality of substrates W is loaded and unloaded, and a processing station 3 that includes a plurality of various processing apparatuses which perform a predetermined processing on the substrate W. The substrate processing system 1 includes an interface station 4 that transfers the substrate W between the cassette station 2 and an exposure device (not illustrated). The exposure device may be provided adjacent to a side of the interface station 4, opposite to the processing station 3. Two processing stations 3 may be installed between the cassette station 2 and the interface station 4, as illustrated in FIGS. 1 and 2. One or more processing stations 3 may be installed between the cassette station 2 and the interface station 4.

The cassette station 2 includes a plurality of cassette stages 2a and substrate transfer apparatuses 2b and 2c. The plurality of cassette stages 2a may be arranged along, for example, an X-direction (a width direction of the substrate processing system 1). Each of the plurality of cassette stages 2a is configured to dispose one cassette 5 thereon.

The substrate transfer apparatuses 2b and 2c are configured to transfer the substrate W between the cassette 5 disposed in the cassette stage 2a and the processing station 3. The substrate transfer apparatuses 2b and 2c are respectively configured to be movable in each of the directions, such as the X-axis direction (horizontal direction), a Y-axis direction (horizontal direction), a Z-axis direction (vertical direction), and a direction around the Z-axis (in a θ-direction). Therefore, each of the substrate transfer apparatuses 2b and 2c may include a drive mechanism in at least one of the X-axis direction, the Y-axis direction, the Z-axis direction, and the θ-direction, or may include a drive mechanism in all of the directions, when necessary.

At least one of the substrate transfer apparatuses 2b and 2c may transfer the substrate W to and from the cassette 5, and may also transfer the substrate W to and from the processing station 3. The transfer of the substrate W to and from the processing station 3 by the substrate transfer apparatuses 2b and 2c may include transferring the substrate W to and from a block G3. An inspection device (not illustrated) that performs an inspection on the substrate W may be provided at a location accessible by at least one of the substrate transfer apparatuses 2b and 2c.

The processing station 3 is configured to perform various kinds of photolithography processing on the substrate W. The processing station 3 may include a plurality of modules 3a stacked in the vertical direction, as illustrated in FIG. 2. As illustrated in FIGS. 1 and 2, each of the modules 3a may include, for example, blocks G1 and G2 and a substrate transfer space 3b extending in the Y-axis direction. The blocks G1 and G2 may be disposed in the X-axis direction to face each other with the substrate transfer space 3b interposed therebetween.

The block G1 includes at least one thin film processing device U1. The thin film processing device U1 may be a device that supplies a processing liquid to the substrate W to perform a film processing, or may be a device that supplies a predetermined gas to the substrate W to perform a film processing. The thin film processing device U1 may include, for example, a thin film forming device, and a development processing device. The thin film forming device may include, for example, a photosensitive thin film forming device, and an anti-reflective film forming device. The photosensitive thin film forming device may be a device for forming a resist film used as a mask when forming a pattern of a film on a bottom layer. The anti-reflective film forming device may be a device for forming an anti-reflective film for efficiently performing a light irradiation processing, such as an exposure processing. The development processing device may be a device for removing a portion of an exposed resist film and forming an uneven shape as the mask. A thin film processing may include forming a thin film and performing a development processing. In an example of FIG. 1, a plurality of thin film processing devices U1 are disposed to be arranged along the Y-axis direction, but the number, the arrangement, and the type of the thin film processing devices U1 may be arbitrarily selected.

The block G2 includes a plurality of heat treatment devices U2, a hydrophobization treatment device (not illustrated), and a peripheral exposure device U3. The plurality of heat treatment devices U2 are configured to perform heat treatment (e.g., heating or cooling) of the substrate W. The plurality of heat treatment devices U2 may be disposed in the block G2 to be arranged in both the vertical direction and the horizontal direction. The hydrophobization treatment device is configured to hydrophobize the surface of the substrate W in order to increase fixability of the substrate W with a treatment liquid which is to be a photosensitive thin film. The peripheral exposure device U3 is configured to expose a portion of the photosensitive thin film formed on the surface of the substrate, which is located at a peripheral edge thereof. The hydrophobization treatment device and the peripheral exposure device U3 may be disposed in the block G2 to be arranged in the vertical direction and the horizontal direction. The number and the arrangement of each of the heat treatment device U2, the hydrophobization treatment device, and the peripheral exposure device U3 may be arbitrarily selected.

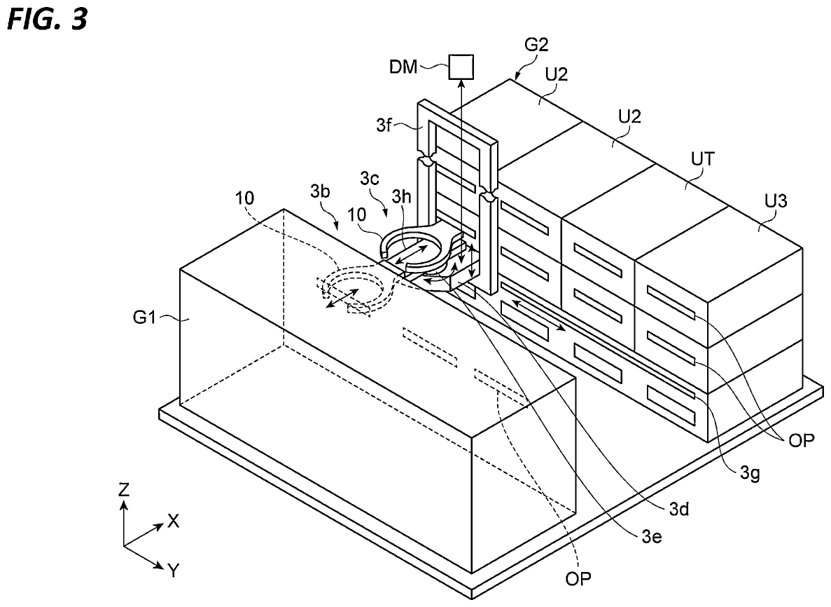

As illustrated in FIG. 1, the substrate transfer space 3b is formed in an area between the blocks G1 and G2 as viewed in plan view. In the substrate transfer space 3b, for example, a substrate transfer apparatus 3c is disposed. The substrate transfer apparatus 3c includes a transfer arm 10 that is movable, for example, in each of the X-direction (horizontal direction), a Y-direction (horizontal direction), a Z-direction (vertical direction), and a direction around a vertical axis (in an θ-direction). The substrate transfer apparatus 3c may include a drive mechanism DM (see, e.g., FIG. 3) for movement in each of the directions.

The substrate transfer apparatus 3c may move within the substrate transfer space 3b and transfer the substrates W to predetermined devices within the blocks G1 and G2 or the blocks G3 and G4 in the surrounding thereof. As illustrated in FIG. 1, when a plurality of processing stations 3 are provided, the substrate transfer apparatus 3c provided in the processing station 3 located on the side of the interface station 4 may transfer the substrate W to a predetermined device in the block G5 (to be described later), in addition to the blocks G1, G2, and G4.

A plurality of substrate transfer apparatuses 3c may be disposed vertically. One substrate transfer apparatus 3c may transfer the substrate W to a predetermined device of the module 3a located on an upper side of the plurality of modules 3a, which are stacked vertically. The other substrate transfer apparatus 3c may transfer the substrate W to a predetermined device of the module 3a located on a lower side of the plurality of modules 3a. For example, the substrate transfer apparatus 3c may be provided for each module 3a, and the number of substrate transfer apparatuses 3c and the number of modules 3a corresponding to one substrate transfer apparatus 3c may be arbitrarily selected.

The substrate transfer space 3b or the blocks G1 and G2 may include a shuttle transfer device (not illustrated). The shuttle transfer device may be configured to transfer the substrate W in a straight line between a space adjacent to one side of the processing station 3 and another space adjacent to the other side of the processing station 3.

The block G3 may be disposed in the cassette station 2 to be near the substrate transfer space 3b of the processing station 3. The block G3 may be provided within the processing station 3. The block G3 may include a plurality of delivery devices (not illustrated) arranged in the vertical direction.

The block G4 is disposed in the substrate transfer space 3b at a boundary portion of the two processing stations 3, in the example of FIG. 1. The block G4 may include a plurality of delivery devices (not illustrated) arranged in the vertical direction. The delivery devices may be configured to be accessible to the substrate transfer apparatus 3c of one of the two processing stations 3 and the substrate transfer apparatus 3c of the other of the two processing stations 3, respectively.

The block G5 may be disposed in the interface station 4 to be located near the substrate transfer space 3b in the processing station 3, in the example of FIG. 1. The block G5 may be disposed within the processing station 3. The block G5 may include a plurality of delivery devices (not illustrated) arranged in the vertical direction. Each of the delivery devices may be configured to be accessible to the substrate transfer apparatus 3c and substrate transfer apparatuses 4a and 4b (to be described below) of the interface station 4.

The interface station 4 connects the processing station 3 and an exposure device (not illustrated) to deliver the substrate W between the processing station 3 and the exposure device (not illustrated). The exposure device may be adjacent to the interface station 4, for example, so as to be located at a side of the interface station 4, opposite to the processing station 3.

The interface station 4 includes the substrate transfer apparatuses 4a and 4b. The substrate transfer apparatuses 4a and 4b are each configured to be movable, for example, in the X-direction (horizontal direction), the Y-direction (horizontal direction), the Z-direction (vertical direction), and the direction around the Z-axis (in the θ-direction). Each of the substrate transfer apparatuses 4a and 4b may include a drive mechanism in at least one of the X-axis direction, the Y-axis direction, the Z-axis direction, and the θ-direction, as necessary, or may include a drive mechanism in all of the directions.

At least one of the substrate transfer apparatuses 4b and 4c may transfer the substrate W to and from the processing station 3 and may also transfer the substrate W to and from the exposure device. The transfer of the substrates W to and from the processing station 3 by the substrate transfer apparatuses 4b and 4c may include the transfer of the substrates W to and from the block G5.

A cleaning device for cleaning the surface of the substrate W and the peripheral exposure device U3 described above may be provided in the interface station 4 at a location that may be accessed by at least one of the substrate transfer apparatuses 4b and 4c.

The inspection device may be provided in the cassette station 2 as described above. The inspection device may be provided in the processing station 3 or the interface station 4 at a location that may be accessed by any one of the substrate transfer apparatuses 3c, 4b and 4c, which are provided inside the processing station 3 or the interface station 4.

The substrate processing system 1 described above includes a controller Ctr (control unit). The controller Ctr is configured to control the substrate processing system 1, either partially or entirely.

### [Details of Substrate Transfer Apparatus]

The details of the substrate transfer apparatus 3c will be described with reference to FIGS. 3 to 8. The substrate transfer apparatuses 2b, 2c, 4a and 4b may also be configured in the same manner as the substrate transfer apparatus 3c.

The substrate transfer apparatus 3c is configured to transfer the substrates W to the blocks G1 to G5, as described above. As illustrated in FIG. 3, the block G2 may include a temporary placement unit UT for correcting a holding position of the substrate W when the substrate W is held by the transfer arm 10. Each of units constituting the blocks G1 to G5 (the thin film processing device U1, the heat treatment device U2, the hydrophobization treatment device, the peripheral exposure device U3, and the delivery device) may include an opening OP in a side wall thereof, which faces the substrate transfer space 3b. The substrate transfer apparatus 3c loads and unloads the substrate W to and from each of the units through the opening OP.

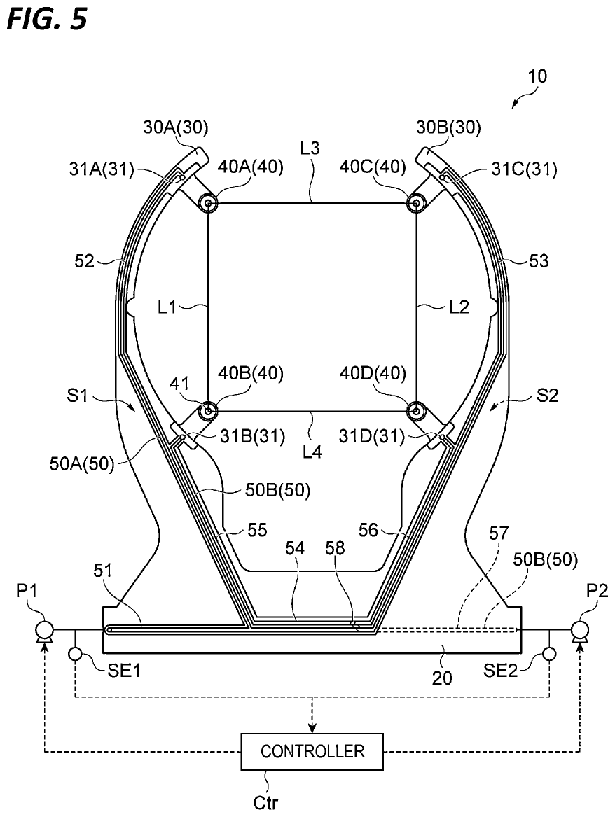

The substrate transfer apparatus 3c includes a lifting stage 3d, a rotation mechanism 3e, a drive mechanism DM (drive unit or driver), at least one transfer arm 10, suction pumps P1 and P2, and sensors SE1 and SE2, as illustrated in FIGS. 3 and 5.

The lifting stage 3d supports the rotation mechanism 3e and the transfer arm 10, as illustrated in FIG. 3. The lifting stage 3d is configured to move vertically along a Z-axis guide rail (not illustrated) extending in the Z-axis direction. The Z-axis guide rail is covered by a cover body 3f. The cover body 3f is configured to slide along a Y-axis guide rail 3g, which extends in a straight line in the Y-axis direction.

The rotation mechanism 3e is mounted on the lifting stage 3d. The rotation mechanism 3e is configured to rotate a base 3h that holds the at least one transfer arm 10 around the Z-axis (in the θ-direction). The drive mechanism DM is configured to perform a vertical movement of the lifting stage 3d along the Z-axis guide rail, a horizontal movement of the cover body 3f along the Y-axis guide rail 3g, a rotational movement of the base 3h by the rotation mechanism 3e, and advance and retreat movements (to be described below) of the at least one transfer arm 10 to the base 3h. The drive mechanism DM may include a rotary motor, and a linear actuator.

The at least one transfer arm 10 is configured to advance and retreat along a longitudinal direction (X-axis direction) of the base 3h. When the substrate transfer apparatus 3c includes a plurality of transfer arms 10, the plurality of transfer arms 10 may be held on the base 3h to overlap each other vertically and may be configured to advance toward and retract from the base 3h independently. A configuration of one transfer arm 10 is described below, but other transfer arms 10 may also be configured in the same manner.

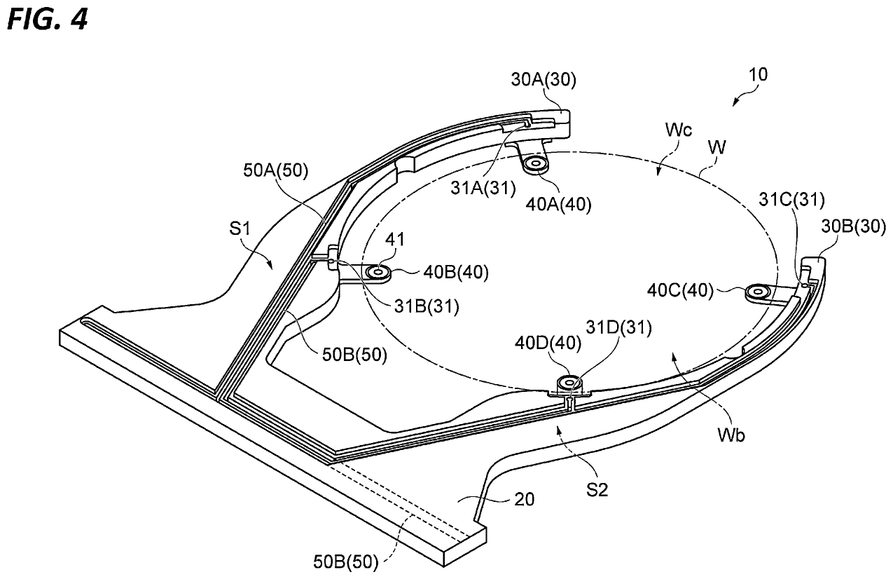

The transfer arm 10 includes a base portion 20, a pair of arm portions 30, four adsorption units (adsorbers) 40, and two suction passages 50, as illustrated in FIGS. 4 to 6.

The base portion 20 and the pair of arm portions 30 have a flat plate shape. The pair of arm portions 30 are integrally connected to the base portion 20 so as to extend in the same direction from the base portion 20. The pair of arm portions 30 extend in an approximately arcuate shape to surround an outer circumference of the substrate W, as illustrated in FIG. 4.

One arm portion 30A (first arm portion) of the pair of arm portions 30 is provided with two connection holes 31 (31A and 31B), as illustrated in FIGS. 4 and 5. The connection holes 31A and 31B extend in a thickness direction of the arm portion 30A so as to penetrate the arm portion 30A. The connection hole 31A is disposed at a front end of the arm portion 30A, and the connection hole 31B is disposed in a side of the arm portion 30A adjacent to the base portion 20.

The other arm portion 30B (second arm portion) of the pair of arm portions 30 is provided with two connection holes 31 (31C and 31D). The connection holes 31C and 31D extend in a thickness direction of the arm portion 30B so as to penetrate the arm portion 30B. The connection hole 31C is disposed at a front end of the arm portion 30B, and the connection hole 31D is disposed in a side of the arm portion 30B adjacent to the base.

Each of the four adsorption units 40 includes a suction port 41 for adsorbing a peripheral edge We of a back surface Wb of the substrate W. Two adsorption units 40A and 40B among the four adsorption units 40 are attached to the arm portion 30A from a lower surface S2 (see, e.g., FIGS. 4 to 6) of the transfer arm 10. Two adsorption units 40C and 40D among the four adsorption units 40 are attached to the arm portion 30B from the lower surface S2 of the transfer arm 10.

As illustrated in FIG. 5, separation distances between adjacent adsorption units 40 may be approximately equal. Specifically, a separation distance L1 between the suction ports 41 of adjacent adsorption units 40A and 40B, a separation distance L2 between the suction ports 41 of adjacent adsorption units 40C and 40D, a separation distance L3 between the suction ports 41 of adjacent adsorption units 40A and 40C, and a separation distance L4 between the suction ports 41 of adjacent adsorption units 40B and 40D may all be approximately equal. The term “approximately equal” herein may include an error of, for example, ±40 mm.

The adsorption unit 40A (first adsorption unit, first adsorption unit group) is located to correspond to the connection hole 31A, and the adsorption unit 40B (third adsorption unit, second adsorption unit group) is located to correspond to the connection hole 31B. For example, the adsorption unit 40A is disposed at the front end of the arm portion 30A, and the adsorption unit 40B is disposed in the side of the arm portion 30A adjacent to the base portion 20.

The adsorption unit 40C (second adsorption unit, first adsorption unit group) is located to correspond to the connection hole 31C, and the adsorption unit 40D (fourth adsorption unit, second adsorption unit group) is located to correspond to the connection hole 31D. For example, the adsorption unit 40C is disposed at the front end of the arm portion 30B, and the adsorption unit 40D is disposed in the side of the arm portion 30B adjacent to the base portion 20.

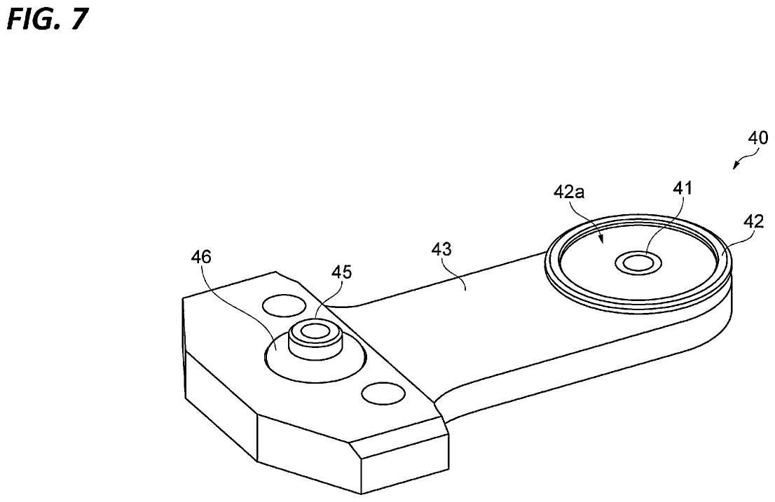

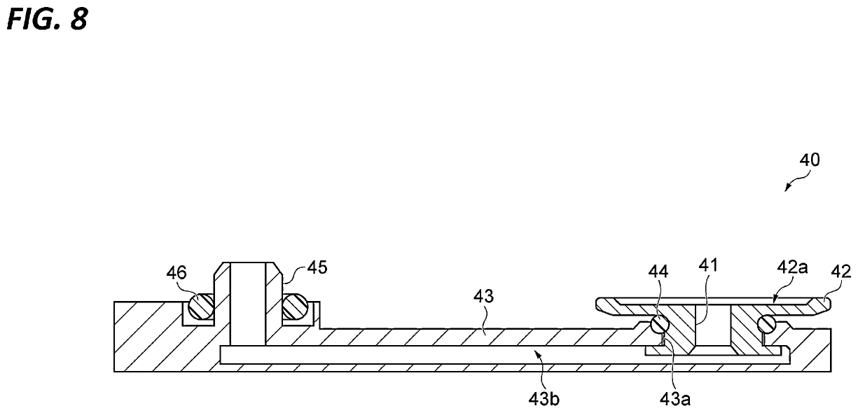

The adsorption unit 40 includes a pad body 42 and a holding member 43, as illustrated in FIGS. 7 and 8. The pad body 42 includes an adsorption surface 42a having an approximately circular shape, which vacuum-adsorbs and holds the substrate W, and the suction port 41 provided at approximately the center of the adsorption surface 42a. The pad body 42 is attached to a through-hole 43a provided at a tip of the holding member 43 through a sealing member 44 (e.g., an O-ring). Accordingly, the suction port 41 is fluidly connected to a flow channel 43b provided inside the holding member 43 in an airtight condition.

A cylindrical connection unit 45 is provided at a base portion of the holding member 43. An inner space of the connection unit 45 is fluidly connected to the flow channel 43b. For example, the flow channel 43b extends from the tip to the base portion of the holding member 43. The connection unit 45 is inserted into and fitted to the connection hole 31 from the lower surface S2 of the transfer arm 10. A sealing member 46 (e.g., O-ring) is attached to an outer circumference of the connection unit 45. Therefore, the inner space of the connection unit 45 and the flow channel 43b are fluidly connected to the connection hole 31 in an airtight manner.

The two suction passages 50 are recessed grooves provided in the base portion 20 and the pair of arm portions 30, as illustrated in FIGS. 4 to 6. A lid member (not illustrated) is attached to an upper portion of the suction passages 50 by an adhesive. As a result, airtightness in the suction passages 50 is maintained.

One suction passage 50A (first suction passage) of the two suction passages 50 extends in an upper surface S1 (one main surface) of the transfer arm 10. Specifically, the suction passage 50A includes a first passage 51, a second passage 52, and a third passage 53, as illustrated in FIG. 5. The first passage 51 extends in the base portion 20 along a width direction of the base portion 20. The second passage 52 branches from the first passage 51 and extends to near the front end of the arm portion 30A. The third passage 53 branches from the first passage 51 and extends to near the front end of the arm portion 30B.

A front end of the second passage 52 is connected to the connection hole 31A. A front end of the third passage 53 is connected to the connection hole 31C. Therefore, the suction passage 50A is fluidly connected to the suction ports 41 of the adsorption units 40A and 40C.

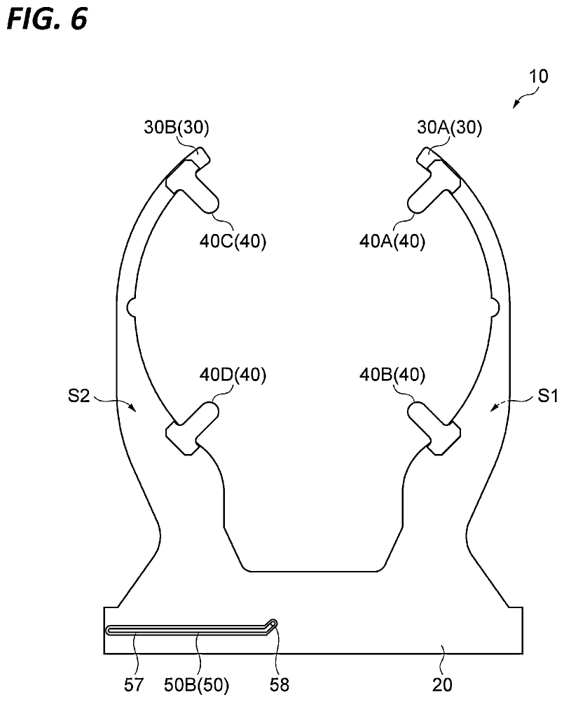

The other suction passage 50B (second suction passage) of the two suction passages 50 extends in the upper surface S1 (one main surface) and the lower surface S2 (another main surface) of the transfer arm 10. Specifically, the suction passage 50B includes a first passage 54 (first portion), a second passage 55 (first portion), a third passage 56 (first portion), and a fourth passage 57 (second portion), as illustrated in FIGS. 5 and 6. The first passage 54 extends along the width direction of the base portion 20 in the upper surface S1 of the base portion 20. The second passage 55 branches from the first passage 54 and extends to near the center of the arm portion 30A. The third passage 56 branches from the first passage 54 and extends to near the center of the arm portion 30B. The fourth passage 57 extends along the width direction of the base portion 20 in the lower surface S2 of the base portion 20.

A front end of the second passage 55 is connected to the connection hole 31B. A front end of the third passage 56 is connected to the connection hole 31D. An end of the fourth passage 57 at the center of the base portion 20 is connected to the first passage 54 through a through-hole 58. The through-hole 58 extends in a thickness direction of the base portion 20 to penetrate the base portion 20. Therefore, the suction passage 50B is fluidly connected to the suction ports 41 of the adsorption units 40B and 40D.

The suction pump P1 is connected to the first passage 51 through a pipe D1. The suction pump P1 operates based on a control signal from the controller Ctr and is configured to generate negative pressure in the suction ports 41 of the adsorption units 40A and 40C through the suction passage 50A. The suction pump P2 is connected to the fourth passage 57 through a pipe D2. The suction pump P2 operates based on a control signal from the controller Ctr and generates negative pressure in the suction ports 41 of the adsorption units 40B and 40D through the suction passage 50B.

The sensor SE1 (first sensor) is configured to detect a magnitude of pressure in the pipe D1. The sensor SE1 is configured to transmit data regarding the detected magnitude of pressure to the controller Ctr. The sensor SE2 (second sensor) is configured to detect a magnitude of pressure in the pipe D2. The sensor SE2 is configured to transmit data regarding the detected magnitude of pressure to the controller Ctr.

### [Details of Controller]

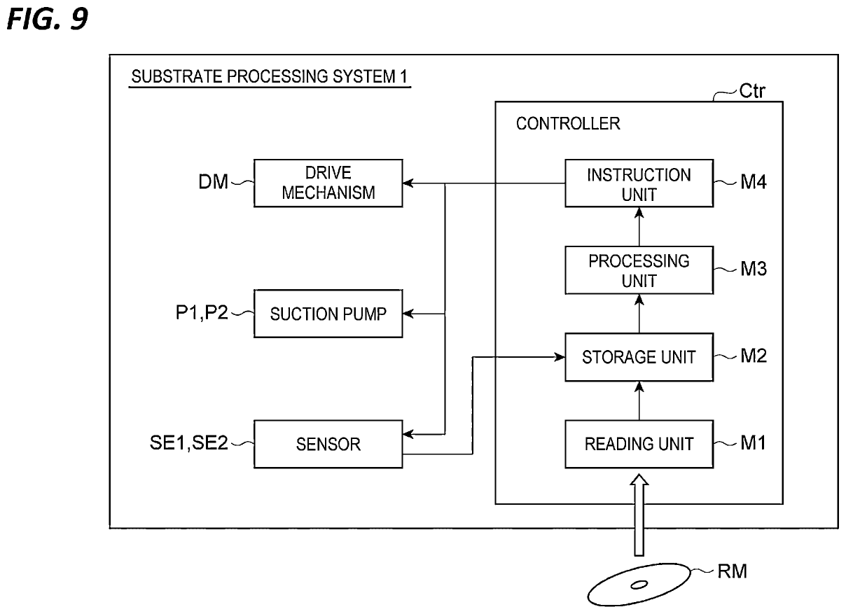

The controller Ctr is configured to control the substrate processing system 1 either partially or entirely. As illustrated in FIG. 9, the controller Ctr includes, as functional modules, a reading unit M1, a storage unit M2, a processing unit M3, an instruction unit M4, and a communication unit M5. The functional modules are merely those obtained by delimiting functions of the controller Ctr into multiple modules for convenience, and do not necessarily mean that the hardware constituting the controller Ctr is divided into the modules. Each functional module is not limited to those implemented by execution of a program, and may also be implemented by dedicated electric circuits (e.g., logic circuits) or an application specific integrated circuit (ASIC) that integrates these circuits.

The reading unit M1 is configured to read a program from a computer-readable recording medium RM. The recording medium RM records a program for operating each part of the substrate processing system 1. The recording medium RM may include, for example, a semiconductor memory, an optical recording disk, a magnetic recording disk, or a magneto-optical recording disk. Hereinafter, each part of the substrate processing system 1 may include a drive mechanism DM, suction pumps P1 and P2, and sensors SE1 and SE2.

The storage unit M2 is configured to store various pieces of data. The storage unit M2 may store, for example, setting data input by an operator through an external input device (not illustrated) or a program read from the recording medium RM in the reading unit M1. The storage unit M2 may store, for example, data regarding processing conditions (processing recipes) for processing the substrate W. The storage unit M2 may store, for example, data regarding the magnitude of pressure detected by the sensors SE1 and SE2.

The processing unit M3 is configured to process various pieces of data. The processing unit M3 may generate a control signal to operate each part of the substrate processing system 1, for example, based on various pieces of data stored in the storage unit M2.

The processing unit M3 may, for example, change a movement speed of the transfer arm 10 by the drive mechanism DM based on results detected by the sensors SE1 and SE2.

Meanwhile, for example, when the back surface Wb of the substrate W is adsorbed by the suction ports 41 of the adsorption units 40A and 40C, a pressure in the suction passage 50A is less than or equal to a predetermined value. Similarly, when the back surface Wb of the substrate W is adsorbed by the suction ports 41 of the adsorption units 40B and 40D, a pressure in the suction passage 50B is less than or equal to the predetermined value. Meanwhile, when the back surface Wb of the substrate W is not adsorbed by the suction port 41 of at least one of the adsorption units 40A and 40C due to warpage of the substrate W, the corresponding at least one suction port 41 is opened. Therefore, due to the vacuuming of the suction passage 50A by the suction pump P1, the pressure in the suction passage 50A continues to be higher than the predetermined value. Similarly, when the back surface Wb of the substrate W is not adsorbed by the suction port 41 of at least one of the adsorption units 40B and 40D due to warpage of the substrate W, the suction port 41 of the at least one of the adsorption units 40B and 40D is opened. Therefore, due to the vacuuming of the suction passage 50B by the suction pump P2, the pressure in the suction passage 50B continues to be higher than the predetermined value.

Therefore, when the pressure is less than or equal to the predetermined value, as a result detected by the sensor SE1, the processing unit M3 may determine that the back surface Wb of the substrate W is adsorbed by the suction ports 41 of the adsorption units 40A and 40C. Similarly, when the pressure is less than or equal to the predetermined value as a result detected by the sensor SE2, the processing unit M3 may determine that the back surface Wb of the substrate W is adsorbed by the suction ports 41 of the adsorption units 40B and 40D.

When it is determined that the back surface Wb of the substrate W is adsorbed by the suction ports 41 of the adsorption units 40A to 40D, the processing unit M3 may control the drive mechanism DM to move the transfer arm 10 at a predetermined speed V1 (first speed). When it is determined that the back surface Wb of the substrate W is adsorbed by the suction ports 41 of the adsorption units 40A and 40C, but not adsorbed by the suction ports 41 of the remaining adsorption units, the processing unit M3 may control the drive mechanism DM to move the transfer arm 10 at a predetermined speed V2 (second speed). Similarly, when it is determined that the back surface Wb of the substrate W is adsorbed by the suction ports 41 of the adsorption units 40B and 40D, but not adsorbed by the suction ports 41 of remaining adsorption units, the processing unit M3 may control the drive mechanism DM to move the transfer arm 10 at the speed V2. Here, the speed V1 may be a transfer speed set in the substrate transfer apparatus 3c. The speed V2 may be a speed lower than the speed V1, for example, about 50% to 90% of the speed V1.

When the back surface Wb of the substrate W is adsorbed by the suction ports 41 of the adsorption units 40A and 40C, but not adsorbed by the suction ports 41 of remaining adsorption units, the adsorption units 40A and 40C (first adsorption unit group) located at front ends of the transfer arm 10 perform an adsorption function. Meanwhile, when the back surface Wb of the substrate W is adsorbed by the suction ports 41 of the adsorption units 40B and 40D but not adsorbed by the suction ports 41 of remaining adsorption units, the adsorption units 40B and 40D (second adsorption unit group) located in the sides of the transfer arm 10 adjacent to the base portion 20 perform an adsorption function. In the case of the transfer arm 10 having a shape illustrated in FIGS. 4 to 6, the speed V2 may be set at, for example, about 90% of the speed V1.

The processing unit M3 may control the drive mechanism DM not to move the transfer arm 10 when the pressure is higher than the predetermined value as results detected by the sensors SE1 and SE2. For example, when the processing unit M3 determines that the back surface Wb of the substrate W is not adsorbed by the suction ports 41 of the adsorption units 40A to 40D, the transfer arm 10 remains stopped. In this case, the processing unit M3 may allow an alarm to be notified from a notification unit, which is not illustrated in the drawings. For example, the notification of the alarm by the notification unit may include displaying an alarm (e.g., a letter or a figure) on a display or issuing an alarm sound or warning from a speaker (not illustrated).

The processing unit M3 may change the movement speed of the transfer arm 10 by the drive mechanism DM, based on the results detected by the sensors SE1 and SE2 and a movement direction of the transfer arm 10. The movement direction may include, for example, at least one of the X-axis direction, the Y-axis direction, the Z-axis direction, and the θ-direction. The processing unit M3 may move the transfer arm 10 at the speed V1 when moving the transfer arm 10 along the Z-axis, for example. The processing unit M3 may move the transfer arm 10 at the speed V2, for example, when moving the transfer arm 10 along one of the X-axis direction, the Y-axis direction, and the θ-direction.

For example, when moving the transfer arm 10 along at least two directions among the X-axis direction, the Y-axis direction, the Z-axis direction, and the θ-direction, the processing unit M3 may pre-calculate a movement time of the transfer arm 10 to a destination and select a path where the transfer arm 10 reaches the destination in the shortest possible time. Specifically, when the transfer arm 10 is set to move at the speed V1 in the Z-axis direction and move at the speed V2 (e.g., 60% of the speed V1) in the Z-axis direction, the processing unit M3 may select a path with the shortest movement time by pre-calculating movement times for a first path where the transfer arm 10 moves linearly to the destination and a second path where the transfer arm 10 moves in the Z-axis direction and X-axis direction, respectively.

The instruction unit M4 is configured to transmit a control signal generated in the processing unit M3 to each part of the substrate processing system 1.

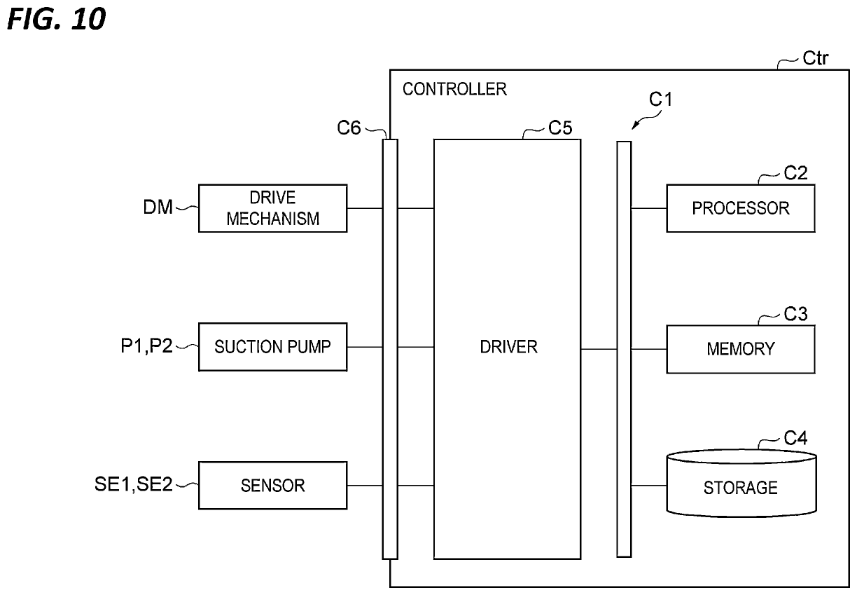

The hardware of the controller Ctr may be configured by, for example, one or more control computers. The controller Ctr may include a circuit C1 as a hardware configuration, as illustrated in FIG. 10. The circuit C1 may include an electrical circuitry. The circuit C1 may include, for example, a processor C2, a memory C3, a storage C4, a driver C5, and an input/output port C6.

The processor C2 may be configured to implement each of the functional modules described above by executing a program in cooperation with at least one of the memory C3 and the storage C4 and by executing input/output of signals through the input/output port C6. The memory C3 and the storage C4 may function as the storage unit M2. The driver C5 may be a circuit configured to drive each part of the substrate processing system 1. The input/output port C6 may be configured to mediate input/output of signals between the driver C5 and each part of substrate processing system 1.

The substrate processing system 1 may include one controller Ctr or a controller group (control unit) including a plurality of controllers Ctr. When the substrate processing system 1 includes a controller group, each of the above functional modules may be implemented by one controller Ctr or by a combination of two or more controller Ctrs. When the controller Ctr includes a plurality of computers (circuit C1), each of the above functional modules may be implemented by a single computer (circuit C1) or may be implemented by a combination of two or more computers (circuit C1). The controller Ctr may include a plurality of processors C2. In this case, each of the above functional modules may be implemented by one processor C2 or may be implemented by a combination of two or more processors C2.

### [Substrate Transfer Method]

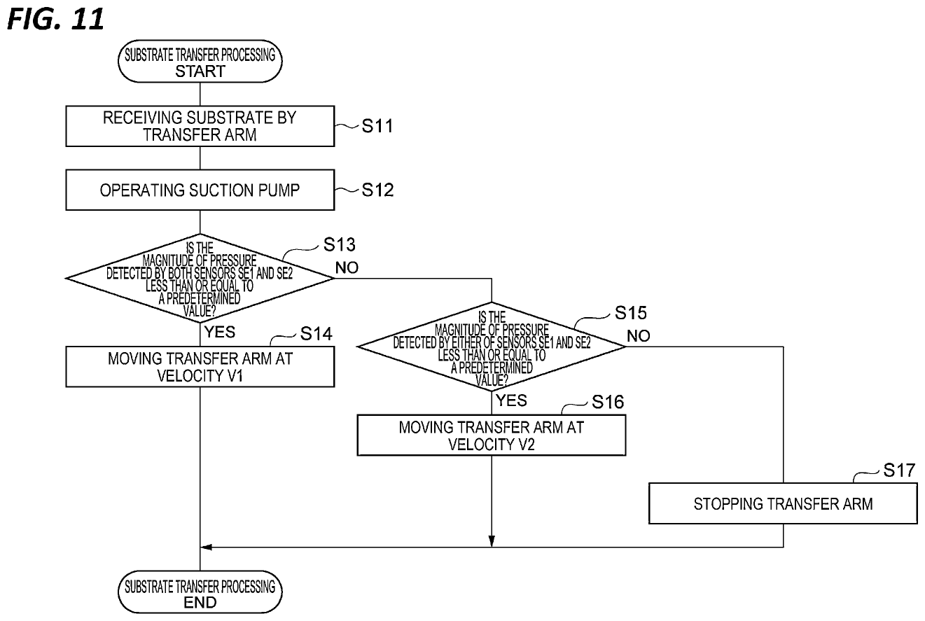

Next, a method of transferring the substrate W by the substrate transfer apparatus 3c will be described with reference to FIG. 11.

First, the transfer arm 10 of the substrate transfer apparatus 3c receives the substrate W from another device (step S11 in FIG. 11). Next, the controller Ctr instructs the suction pumps P1 and P2 to perform a vacuum processing through the suction passage 50, thereby generating negative pressure in the suction port 41 of the adsorption unit 40 (step S12 in FIG. 11).

In step S12, the controller Ctr may operate the suction pump P1 to generate negative pressure in the suction ports 41 of the adsorption units 40A and 40C. Then, the controller Ctr may operate the suction pump P2 to generate negative pressure in the suction ports 41 of the adsorption units 40B and 40D. In this case, the back surface Wb of the substrate W is adsorbed first by the suction ports 41 of the adsorption units 40A and 40C (first adsorption unit group) located at the front ends of the arm portions 30A and 30B. Therefore, compared to a case where the back surface Wb of the substrate W is adsorbed by the suction ports 41 of the adsorption units 40B and 40D (second adsorption unit group) located at sides of the arm portions 30A and 30B adjacent to the base portion 20, the substrate W tends to be easily adsorbed and held on the transfer arm 10. Therefore, even when inertial force acts on the substrate W when the transfer arm 10 moves in an extension direction of the arm portion 30 or centrifugal force acts on the substrate W when the transfer arm 10 rotates in the θ-direction, it is possible to properly transfer the substrate W.

Next, the controller Ctr determines whether both magnitudes of the pressure detected by the sensors SE1 and SE2 are less than or equal to a predetermined value (step S13 in FIG. 11). As a result of the determination by the controller Ctr, when the magnitudes of the pressure detected by both sensors SE1 and SE2 are less than or equal to the predetermined value (“YES” in step S13 of FIG. 11), the controller Ctr may control the drive mechanism DM to move the transfer arm 10 to a destination at a speed V1 (step S14 in FIG. 11). When the transfer arm 10 reaches the destination at the speed V1, the transfer of the substrate W is completed.

Meanwhile, as the result of the determination by the controller Ctr, when magnitudes of the pressure detected by both sensors SE1 and SE2 are not less than the predetermined value (“NO” in step S13 of FIG. 11), the controller Ctr proceeds to step S15. In step S15, the controller Ctr determines whether the pressure detected by one of the sensors SE1 and SE2 is less than or equal to the predetermined value (step S15 in FIG. 11).

As the result of the determination by the controller Ctr, the pressure detected by one of the sensors SE1 and SE2 is less than or equal to the predetermined value (“YES” in step S15 of FIG. 11), the controller Ctr may control the drive mechanism DM to move the transfer arm 10 at a speed V2 to the destination (step S16 in FIG. 11). When the transfer arm 10 reaches the destination at the speed V1, the transfer of the substrate W is completed. When a path to the destination of the transfer arm 10 includes a movement in the Z-axis direction, the transfer arm 10 may move at the speed V1 for the movement in the Z-axis direction.

Meanwhile, as the result of the determination by the controller Ctr, when the pressure detected by one of the sensors SE1 and SE2 is not less than or equal to a predetermined value (“NO” in step S15 of FIG. 11), the controller Ctr controls the drive mechanism DM to keep the transfer arm 10 stopped (step S17 of FIG. 11). In this case, the controller Ctr may control the notification unit (not illustrated) to issue an alarm from the notification unit. Accordingly, the transfer of the substrate W is completed.

### [Actions]

According to the above example, by suction through the suction passage 50, the substrate W is adsorbed in at least one of the suction ports 41 of the first adsorption unit group (adsorption units 40A and 40C) and the suction ports 41 of the second adsorption unit group (adsorption units 40B and 40D). Accordingly, even when the substrate W is warped, the substrate W is adsorbed and held in at least two adsorption units 40. Therefore, even when the substrate W is not flat with warpage, it is possible to properly transfer the substrate W.

According to the above example, when a drop in pressure is detected by the sensor SE1, it may be determined that the substrate W is adsorbed in the suction ports 41 of the first adsorption unit group (the adsorption units 40A and 40C). Similarly, when a drop in pressure is detected by the sensor SE2, it may be determined that the substrate W is adsorbed in the suction ports 41 of the second adsorption unit group (the adsorption units 40B and 40D). In this case, based on the results detected by the sensors SE1 and SE2, it is determined whether the substrate W is adsorbed by the suction ports 41 of the first adsorption unit group, the suction ports 41 of the second adsorption unit group, or the suction ports 41 of the first and second adsorption unit groups. Therefore, by changing the movement speed of the transfer arm 10 according to the number of the suction ports 41 that adsorb the substrate W, it is possible to properly transfer the substrate W while preventing the misalignment of the substrate W with respect to the transfer arm 10 and the dropout of the substrate W from the transfer arm 10.

According to the above example, the movement speed of the transfer arm 10 may be controlled, based on the movement direction of the transfer arm 10, in addition to the results detected by the sensors SE1 and SE2. In this case, by changing the movement speed of the transfer arm 10 in consideration of a magnitude of inertial force acting on the substrate W in addition to an adsorption status of the substrate W, the substrate W may be properly transferred while preventing the misalignment of the substrate W with respect to the transfer arm 10 and the dropout of the substrate W from the transfer arm 10.

According to the above example, as the results detected by the sensors SE1 and SE2, when it is determined that the back surface Wb of the substrate W is adsorbed by the suction ports 41 of the adsorption units 40A to 40D, the transfer arm 10 may move at the speed V1. In this case, since the substrate W is adsorbed by the suction ports 41 of the four adsorption units 40A to 40D, it is difficult to cause the misalignment of the substrate W with respect to the transfer arm 10 or the dropout of the substrate W from the transfer arm 10. Therefore, the transfer arm 10 may move at a relatively fast speed V1, so that it is possible to efficiently transfer the substrate W.

Meanwhile, compared to a case where the substrate W is adsorbed by the suction ports 41 of four adsorption units 40, when the substrate W is adsorbed by the suction ports 41 of two adsorption units 40, a holding property of the substrate W to the transfer arm 10 is relatively low. However, according to the above example, as the results detected by the sensors SE1 and SE2, when it is determined that the back surface Wb of the substrate W is adsorbed by the suction ports 41 of two of the four adsorption units 40, the transfer arm 10 may move at the speed V2 lower than the speed V1. In this case, even when the substrate W is adsorbed by the suction ports 41 of the two adsorption units 40, it is possible to transfer the substrate W properly without stopping the transfer of the substrate W as an adsorption error, while preventing the misalignment of the substrate W with respect to the transfer arm 10 and the dropout of the substrate W from the transfer arm 10.

According to the above example, when it is determined that the substrate W is not adsorbed by the suction ports 41 of the first adsorption unit group and the second adsorption unit group, the transfer arm 10 may be stopped as an adsorption error. In this case, it is possible to prevent the substrate W from being transferred when the holding property of the substrate W to the transfer arm 10 is extremely low.

According to the above example, the arm portions 30A and 30B may extend in the same direction from the base portion 20. The adsorption unit 40A may be disposed at the front end of the arm portion 30A, the adsorption unit 40B may be disposed in the side of the arm portion 30A adjacent to the base portion 20, the adsorption unit 40C may be disposed at the front end of the arm portion 30B, and the adsorption unit 40D may be disposed in the side of the arm portion 30B adjacent to the base portion 20. In this case, even when the substrate W is warped, the substrate W is adsorbed and held in at least two adsorption units 40. More particularly, in this case, the adsorption units 40A and 40C constituting the first adsorption unit group may be located at the front ends of the arm portions 30A and 30B, respectively, and the adsorption units 40B and 40D constituting the second adsorption unit group may be located in the sides of the arm portions 30A and 30B, respectively, adjacent to the base portion 20. Accordingly, the substrate W is adsorbed on at least one of the front ends and the sides of the arm portions 30A and 30B adjacent to the base portion 20. Therefore, even when the substrate W is not flat with warpage, the substrate W may be properly transferred by the transfer arm 10.

According to the above example, the suction passage 50A may be provided in the upper surface S1 of the transfer arm 10. The suction passage 50B may include the first to third passages 54 to 56 that are provided in the upper surface S1 of the transfer arm 10, and the fourth passage 57 that is in communication with the first passage 54 through the through-hole 58 in the transfer arm 10 and that is provided on the lower surface S2 of the transfer arm 10. In this case, the suction passages 50A and 50B, which are suction passages 50 of different systems, pass through the upper surface S1 or the lower surface S2 of the transfer arm 10 and are fluidly independent from each other. Therefore, while shortening paths of the suction passages 50A and 50B, it is possible to adsorb the substrate W in the suction port 41 connected to the suction passage 50A and the suction port 41 connected to the suction passage 50B, independently.

According to the above example, the drive mechanism DM may move the transfer arm 10 along at least one of the X-axis direction, the Y-axis direction, the Z-axis direction, and the θ-direction. In this case, the substrate W may be transferred in various directions by the transfer arm 10.

According to the above example, the transfer arm 10 may move along the Z-axis at the speed V1. When the substrate W is transferred along the Z-axis direction (vertical direction), it is difficult to cause the misalignment of the substrate W with respect to the transfer arm 10 and the dropout of the substrate W from the transfer arm 10. Therefore, the transfer arm 10 may move at a relatively fast speed V1, so that it is possible to efficiently transfer the substrate W.

Meanwhile, when a substrate W is transferred along one of the X-axis, Y-axis, and θ-directions, compared to a case where the substrate is transferred along the Z-axis direction (vertical direction), the misalignment of the substrate W with respect to the transfer arm 10 or dropout of the substrate W from the transfer arm 10 due to the action of inertial force on the substrate W may be relatively easily caused. However, according to the above example, the transfer arm 10 may move along any one of the X-axis direction, the Y-axis direction, and the θ-direction at a speed V2 slower than the speed V1. In this case, since inertial force acting on the substrate W is lowered, it is possible to properly transfer the substrate W while preventing the misalignment of the substrate W with respect to the transfer arm 10 and the dropout of the substrate W from the transfer arm 10.

### [Variations]

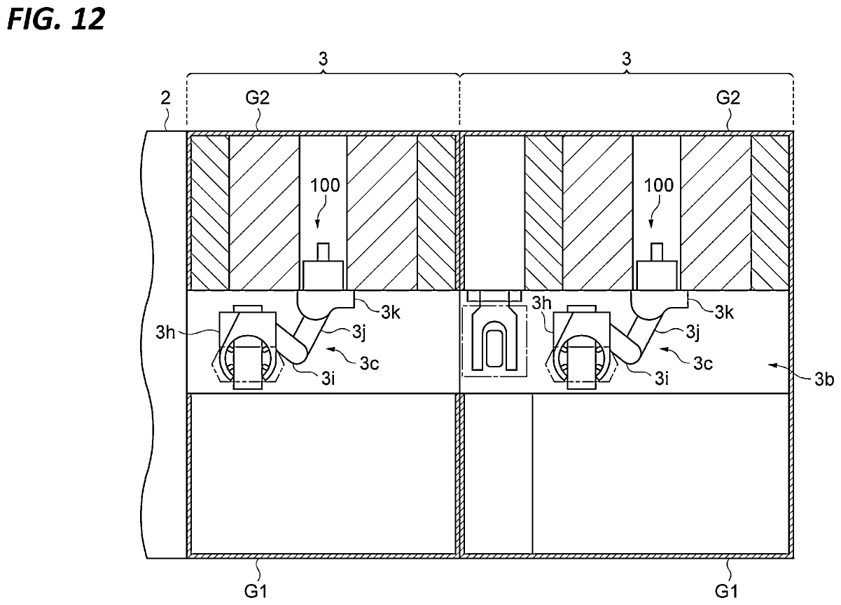

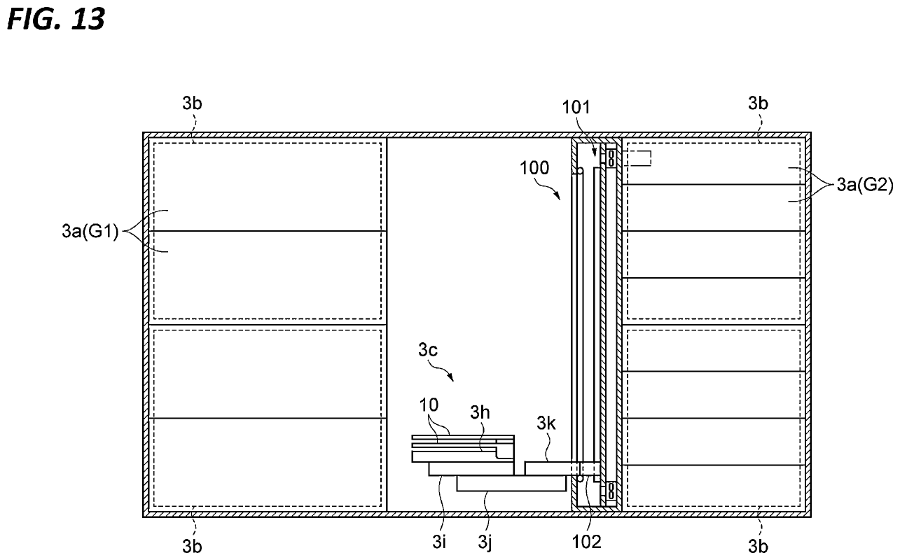

(1) The substrate processing system 1 in the present disclosure is not limited to the configuration or operations described above. For example, in the above example, it is explained that the substrate W is conveyed between the interface station 4 and the exposure device, but the substrate processing system 1 may not be directly connected to the exposure device. In this case, for example, the substrate W is transferred from the cassette station 2 to the processing station 3 and is subjected to a necessary processing. Then, the processed substrate W is transferred again to the cassette station 2 for unloading to the outside. The substrate processing system 1 may not include any of the devices exemplified as processing devices, and the processing of the substrate W may not be performed in the devices.
(2) The substrate transfer apparatus 3c may be configured as illustrated in FIGS. 12 to 14. More particularly, the substrate transfer apparatus 3c includes arm portions 3i and 3j, a base portion 3k, and a support 100. A front end of the arm portion 3i is connected to the base 3h to be pivotable around the Z-axis (in the θ-direction), as illustrated in FIGS. 12 and 13. A front end of the arm portion 3j is connected to a base of the arm portion 3i to be pivotable around the Z-axis (in the θ-direction). A base of the arm portion 3j is connected to the base portion 3k to be pivotable around the Z-axis (in the θ-direction). The arm portions 3i and 3j mutually pivot, so that the base 3h and the transfer arm 10 advance to and retreat from the base portion 3k.

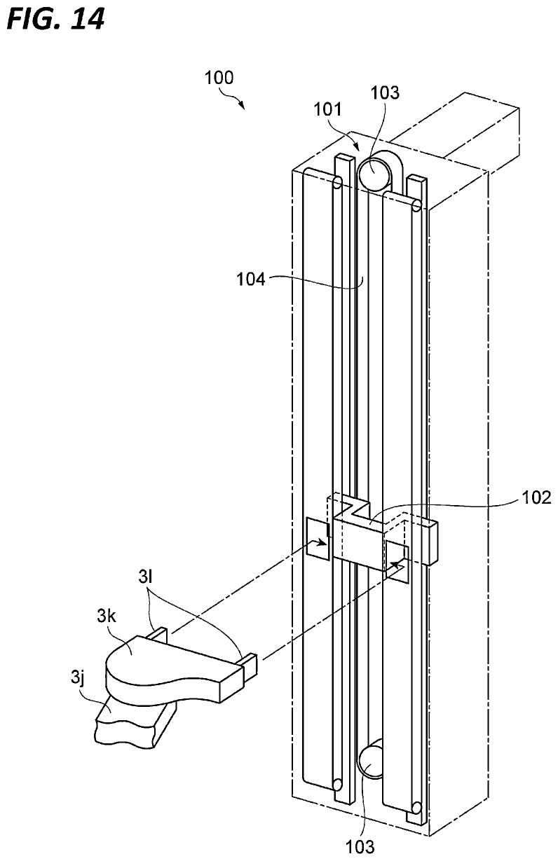

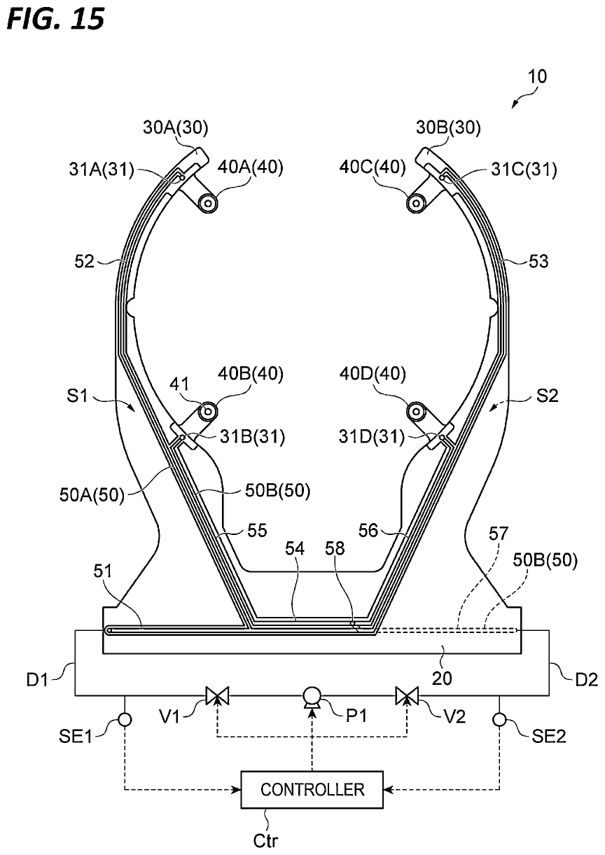

The support 100 includes a lifting mechanism 101 and a slider 102, as illustrated in FIGS. 13 and 14. The lifting mechanism 101 is configured to move the slider 102 vertically. The lifting mechanism 101 may, for example, be configured by an endless belt 104 installed on a pair of pulleys 103. In this case, the slider 102 may be connected to the endless belt 104. The slider 102 is connected to the base portion 3k through a connection member 3. Therefore, according to an operation of the lifting mechanism 101, the transfer arm 10 moves vertically through the slider 102, the connection member 31, the base portion 3k, and the arm portions 3i, and 3j.
(3) As illustrated in FIG. 15, the substrate transfer apparatus 3c may perform a vacuum processing of the suction passages 50A and 50B by the suction pump P1, the sensors SE1 and SE2, and valves VL1 and VL2. The suction pump P1 is connected to the first passage 51 through the pipe D1 and is connected to the fourth passage 57 through the pipe D2. The pipe D1 is provided with the sensor SE1 and the valve VL1. The pipe D2 is provided with the sensor SE2 and the valve VL2. The valves VL1 and VL2 are configured to open and close the pipes D1 and D2, respectively, according to a control signal from the controller Ctr.

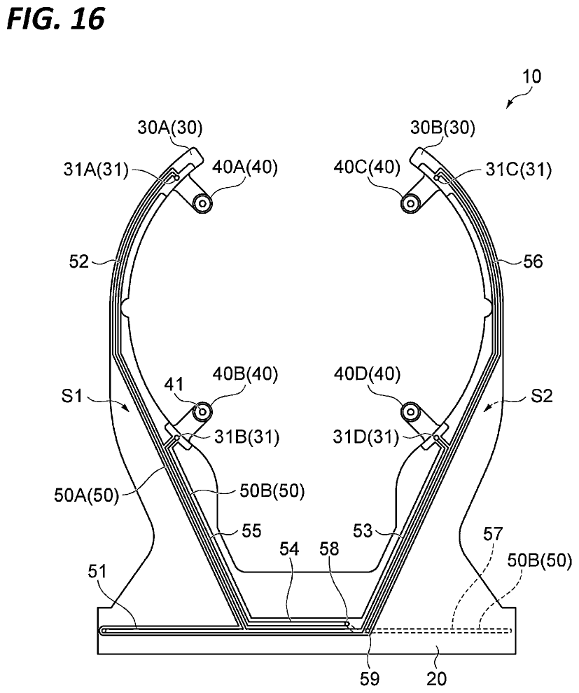

According to the example in FIG. 15, the controller Ctr instructs the suction pump P1 and the valves VL1 and VL2 to open the valves VL1 and VL2. In a state where the valves VL1 and VL2 are open, the controller Ctr performs a vacuum processing through the suction passages 50A and 50B, thereby generating negative pressure in the suction ports 41 of the adsorption units 40. At this time, when the substrate W is adsorbed in the suction ports 41 of the adsorption units 40A to 40D, since magnitudes of the pressure detected by the sensors SE1 and SE2 are both less than or equal to a predetermined value, the controller Ctr maintains the valves VL1 and VL2 in the open state. Meanwhile, when the substrate W is adsorbed in the suction ports 41 of the first adsorption unit group (adsorption units 40A and 40C) and the substrate W is not adsorbed in the suction ports 41 of the second adsorption unit group (adsorption units 40B and 40D), the pressure detected by the sensor SE2 becomes higher than the predetermined value. Therefore, the controller Ctr closes the valve VL2 while maintaining the valve VL1 open. Similarly, when the substrate W is adsorbed in the suction ports 41 of the second adsorption unit group (adsorption units 40B and 40D) and the substrate W is not adsorbed in the suction ports 41 of the first adsorption unit group (adsorption units 40A and 40C), the pressure detected by the sensor SE1 becomes higher than the predetermined value. Therefore, the controller Ctr closes the valve VL1 while maintaining the valve VL2 open. The controller Ctr may close the valves VL1 and VL2 after a predetermined time has elapsed since magnitudes of the pressure detected by the sensors SE1 and SE2 became higher than the predetermined value.
(4) The two suction passages 50 may be configured as illustrated in FIG. 16. More particularly, the suction passage 50A extends in the upper surface S1 of the transfer arm 10. The suction passage 50A includes the first passage 51, the second passage 52, and the third passage 53. The first passage 51 extends in the base portion 20 along the width direction of the base portion 20. The second passage 52 branches from the first passage 51 and extends to near the front end of the arm portion 30A. The third passage 53 branches from the first passage 51 and extends to near the center of the arm portion 30B.

The front end of the second passage 52 is connected to the connection hole 31A. The front end of the third passage 53 is connected to the connection hole 31D. Therefore, the suction passage 50A is fluidly connected to the suction ports 41 of the adsorption units 40A and 40D. For example, the adsorption units 40A and 40D, which constitute a first adsorption unit group are located on a diagonal line of the arm portions 30A and 30B, respectively.

The suction passage 50B extends in the upper surface S1 and the lower surface S2 of the transfer arm 10. The suction passage 50B includes the first passage 54, the second passage 55, the third passage 56, and the fourth passage 57. The first passage 54 extends along the width direction of the base portion 20 in the upper surface S1 of the base portion 20. The second passage 55 branches from the first passage 54 and extends to near the center of the arm portion 30A. The third passage 54 extends from the base portion 20 to near the center of the arm portion 30B in the outside of the third passage 53 of the suction passage 50A. The fourth passage 57 extends along the width direction of the base portion 20 in the lower surface S2 of the base portion 20.

An end of the first passage 54 adjacent to the arm portion 30B is connected to the fourth passage 57 through the through-hole 58. The front end of the second passage 55 is connected to the connection hole 31B. The front end of the third passage 56 is connected to the connection hole 31C. An end of the third passage 56 adjacent to the base portion 20 is connected to the fourth passage 57 through a through-hole 59. The through-holes 58 and 59 extend in the thickness direction of the base portion 20 to penetrate the base portion 20. Therefore, the suction passage 50B is fluidly connected to the suction ports 41 of the adsorption units 40B and 40C. For example, the adsorption units 40B and 40C, which constitute a second adsorption unit group are located on a diagonal line of the arm portions 30A and 30B, respectively.

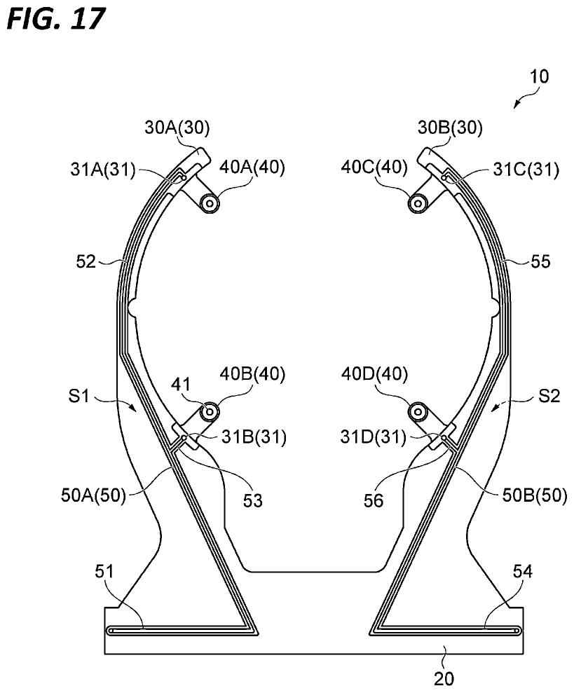

According to a shape illustrated in FIG. 16, even when the substrate W is warped, the substrate W is held in at least two adsorption units 40. Therefore, even when the substrate W is not flat with warpage, the substrate W may be properly transferred by the transfer arm 10. According to the shape illustrated in FIG. 16, the adsorption units 40A and 40D constituting the first adsorption unit group are respectively located on one diagonal line of the arm portions 30A and 30B, and the adsorption units 40B and 40C constituting the second adsorption unit group are respectively located on another diagonal of the arm portions 30A and 30B. Therefore, even when centrifugal force acts on the substrate W when the transfer arm 10 rotates, the substrate W may be properly transferred.
(5) The two suction passages 50 may be configured as illustrated in FIG. 17. More particularly, the suction passage 50A extends in the upper surface S1 of the transfer arm 10. The suction passage 50A includes a first passage 51, a second passage 52, and a third passage 53. The first passage 51 extends along the width direction of the base portion 20 in a side of the base portion 20 adjacent to the arm portion 30A. The second passage 52 extends from the first passage 51 to near the front end of the arm portion 30A. The third passage 53 branches and extends from near the center of the second passage 52.

The front end of the second passage 52 is connected to the connection hole 31A. The front end of the third passage 53 is connected to the connection hole 31B. Therefore, the suction passage 50A is fluidly connected to the suction ports 41 of the adsorption units 40A and 40B. For example, both the adsorption units 40A and 40B, which constitute a first adsorption unit group, are disposed in the arm portion 30A.

The suction passage 50B extends in the upper surface S1 of the transfer arm 10. The suction passage 50B includes a first passage 54, a second passage 55, and a third passage 56. The first passage 54 extends along the width direction of the base portion 20 in a side of the base portion 20 adjacent to the arm portion 30B. The second passage 55 extends from the first passage 54 to near the front end of the arm portion 30B. The third passage 56 branches and extends from near the center of the second passage 55.

The front end of the second passage 55 is connected to the connection hole 31C. The front end of the third passage 56 is connected to the connection hole 31D. Therefore, the suction passage 50B is fluidly connected to the suction ports 41 of the adsorption units 40C and 40D. For example, both the adsorption units 40C and 40D, which constitute a second adsorption unit group, are disposed in the arm portion 30B.

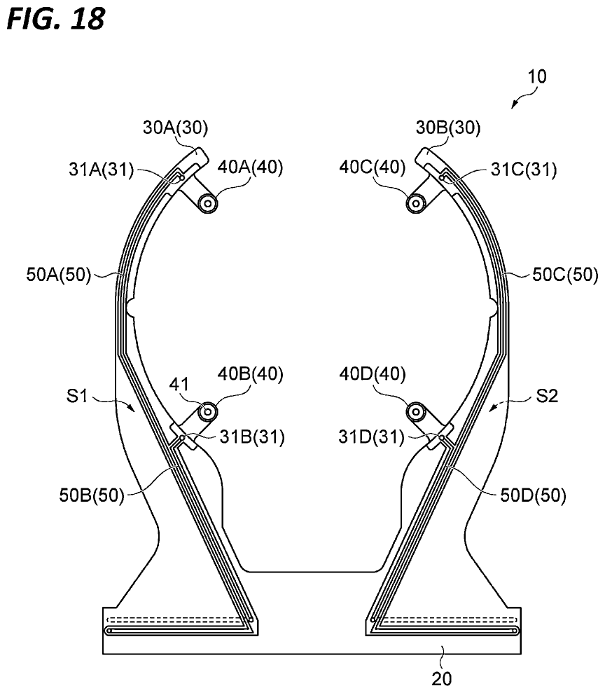

According to the shape illustrated in FIG. 17, the adsorption units 40A and 40B, which constitute a first adsorption unit group, are located on the arm portion 30A, and the adsorption units 40C and 40D, which constitute a second adsorption unit group, are located on the arm portion 30B. Therefore, even when the substrate W is warped, the substrate W is adsorbed and held in at least two adsorption units 40. Accordingly, even when the substrate W is not flat with warpage, the substrate W may be properly transferred by the transfer arm 10. When the substrate W is adsorbed by the suction ports 41 of the adsorption units 40A and 40B constituting the first adsorption unit group or the suction ports 41 of the adsorption units 40C and 40D constituting the second adsorption unit group, the speed V2 may be set to about 50% of the speed V1.
(6) The transfer arm 10 may include four suction passages 50 (50A to 50D), as illustrated in FIG. 18. The suction passage 50A extends in the upper surface S1 of the transfer arm 10. The suction passage 50A extends from an area of the base portion 20 adjacent to the arm portion 30A to near the front end of the arm portion 30A. A front end of the suction passage 50A is connected to the connection hole 31A.

The suction passage 50B extends in the upper surface S1 and the lower surface S2 of the transfer arm 10. The suction passage 50B includes a portion extending to the area of the base portion 20 adjacent to the arm portion 30A in the lower surface S2 and a portion extending to near the center of the arm portion 30A in the upper surface S1. These portions are connected by a through-hole. A front end of the suction passage 50B is connected to the connection hole 31B. The suction passage 50B may extend in the upper surface S1 so as not to intersect with the other suction passage 50.

The suction passage 50C extends in the upper surface S1 of the transfer arm 10. The suction passage 50C extends from an area of the base portion 20 adjacent to the arm portion 30B to near the front end of the arm portion 30A. A front end of the suction passage 50C is connected to the connection hole 31C.

The suction passage 50D extends in the upper surface S1 and the lower surface S2 of the transfer arm 10. The suction passage 50D includes a portion extending to an area of the base portion 20 adjacent to the arm portion 30B in the lower surface S2 and a portion extending to near the center of the arm portion 30B in the upper surface S1. These portions are connected by a through-hole. A front end of the suction passage 50D is connected to the connection hole 31D. The suction passage 50D may extend in the upper surface S1 so as not to intersect with the other suction passage 50.

According to a shape illustrated in FIG. 18, by suction through a plurality of the suction passages 50A to 50D, the substrate W is adsorbed in the suction ports 41 of at least two adsorption units 40 among the plurality of adsorption unit 40A to 40D. For example, even when the substrate W is warped, the substrate W is adsorbed and held in at least two adsorption units 40. Therefore, even when the substrate W is not flat with warpage, the substrate W may be properly transferred by the transfer arm 10.

In the shape illustrated in FIG. 18, the substrate transfer apparatus 3c may include a plurality of suction pumps. Each of the suction pumps may be connected to corresponding suction passages 50A to 50D, respectively, and may be configured to generate negative pressure in the suction ports 41 of the respective adsorption units 40A to 40D through the respective suction passages 50A to 50D. The substrate transfer apparatus 3C may also include a plurality of sensors configured to detect the pressure in each of suction passages 50A to 50D.

In the shape illustrated in FIG. 18, as results detected by the plurality of sensors, when the substrate W is adsorbed by the suction ports 41 of three or more adsorption units 40 among the plurality of adsorption unit 40, the transfer arm 10 may move at the speed V1. As the results detected by the plurality of sensors, when the substrate W is adsorbed by the suction ports 41 of two adsorption units 40 among the plurality of adsorption units 40, the transfer arm 10 may move at a speed V2 slower than the speed V1. As the results detected by the plurality of sensors, when the substrate W is adsorbed by the suction port 41 of one or less adsorption unit 40 among the plurality of adsorption units 40, the transfer arm 10 may not be moved.

### OTHER EXAMPLES

Example 1: An example of a substrate transfer apparatus includes a transfer arm, a drive unit that moves the transfer arm; and a control unit that controls the drive unit. The transfer arm includes a base portion, at least one arm portion connected to the base portion to extend from the base portion and configured to surround an outer circumference of a substrate, a plurality of adsorption units provided in the at least one arm portion and each including a suction port that adsorbs a peripheral edge of a back surface of the substrate, and a plurality of suction passages provided in the at least one arm portion. The plurality of adsorption units include a first adsorption unit group including a first adsorption unit and a second adsorption unit; and a second adsorption unit group including a third adsorption unit and a fourth adsorption unit. The plurality of suction passages include a first suction passage connected to the suction ports of the first adsorption unit and the second adsorption unit, and a second suction passage connected to the suction ports of the third adsorption unit and the fourth adsorption unit. In this case, by suction through the first and second suction passages, the substrate is adsorbed in at least one of the suction ports of the first adsorption unit group (first and second adsorption units) and the suction ports of the second adsorption unit group (third and fourth adsorption units). Therefore, even when the substrate is warped, the substrate is adsorbed and held in at least two adsorption units. Therefore, even when the substrate is not flat with warpage, the substrate may be properly transferred by the transfer arm.

Example 2: The substrate transfer apparatus of Example 1 may further include a first sensor configured to detect pressure in the first suction passage, and a second sensor configured to detect pressure in the second suction passage. The control unit may be configured to change a movement speed of the transfer arm by the drive unit based on results detected by the first sensor and the second sensor. In this case, when a drop in pressure is detected by the first sensor, it is determined that the substrate is adsorbed in the suction ports of the first adsorption unit group. Similarly, when a drop in pressure is detected by the second sensor, it is determined that the substrate is adsorbed in the suction ports of the second adsorption unit group. Therefore, based on the results detected by the first and second sensors, it is determined whether the substrate is adsorbed by the suction ports of the first adsorption unit group, the suction ports of the second adsorption unit group, or the suction ports of the first and second adsorption unit groups. Therefore, by changing the movement speed of the transfer arm according to the number of suction ports that adsorb the substrate, the substrate may be properly transferred while preventing misalignment of the substrate with respect to the transfer arm and the dropout of the substrate from the transfer arm.

Example 3: In the substrate transfer apparatus of Example 2, the control unit may be configured to change the movement speed of the transfer arm by the drive unit, based on the results detected by the first sensor and the second sensor, and a movement direction of the transfer arm. A magnitude of inertial force acting on the substrate may vary according to the movement direction of the transfer arm. However, according to Example 2, the movement speed of the transfer arm is controlled based on the movement direction of the transfer arm in addition to the results detected by the first and second sensors. Therefore, by changing the movement speed of the transfer arm in consideration of the magnitude of inertial force acting on the substrate in addition to an adsorption status of the substrate, it is possible to transfer the substrate properly while preventing misalignment of the substrate with respect to the transfer arm and dropout of the substrate from the transfer arm.

Example 4: In the substrate transfer apparatus of Example 2 or Example 3, when it is determined that the back surface of the substrate is adsorbed by the suction ports of the first to fourth adsorption units, from the results detected by the first sensor and the second sensor, the control unit may be configured to control the drive unit to move the transfer arm at a first speed. In this case, since the substrate is adsorbed by the suction ports of the four adsorption units, it is difficult to cause the misalignment of the substrate with respect to the transfer arm or dropout of the substrate from the transfer arm. Therefore, the substrate may be efficiently transferred by moving the transfer arm at a relatively fast first speed.

Example 5: In the substrate transfer apparatus of Example 4, when it is determined that a pressure of one of the first suction passage and the second suction passage is higher than a threshold value set in advance, and a pressure of the other of the first suction passage and the second suction passage is less than or equal to the threshold value, from the results detected by the first sensor and the second sensor, the control unit may be configured to control the drive unit to move the transfer arm at a second speed slower than the first speed. In this case, the substrate is adsorbed by the suction ports of the two adsorption units. Therefore, a holding property of the substrate to the transfer arm is relatively low, compared to a case in which the substrate is adsorbed by the suction ports of the four adsorption units. However, in Example 5, the transfer arm is moved at a second speed that is slower than the first speed. Therefore, since the inertial force acting on the substrate is lowered, even when the substrate is adsorbed by the suction ports of the two adsorption units, the substrate may be properly transferred while preventing misalignment of the substrate with respect to the transfer arm and dropout of the substrate from the transfer arm without stopping the transfer of the substrate as an adsorption error.

Example 6: In the substrate transfer apparatus of Example 2, the control unit may be configured to perform: in response to the results detected by the first sensor and the second sensor, controlling the drive unit to move the transfer arm at a first speed when it is determined that the back surface of the substrate is adsorbed by the suction ports of the first adsorption unit group and the suction ports of the second adsorption unit group, controlling the drive unit to move the transfer arm at a second speed slower than the first speed when it is determined that the back surface of the substrate is adsorbed by the suction ports of the first adsorption unit group or the suction ports of the second adsorption unit group, and controlling the drive unit not to move the transfer arm when it is determined that the back surface of the substrate is adsorbed by one or less of the suction ports of the first adsorption unit group and the second adsorption unit group. In this case, the same effects as those of the substrate transfer apparatuses in Examples 4 and 5 are obtained. In the case of Example 6, when the substrate is adsorbed by the suction port of one or less adsorption unit, the transfer of the substrate is stopped as an adsorption error. Therefore, it is possible to prevent the substrate from being transferred when the holding property of the substrate to the transfer arm is extremely low.

Example 7: In the substrate transfer apparatus of any one of Examples 1 to 6, the at least one arm portion includes a pair of first and second arm portions extending in the same direction from the base portion. The first adsorption unit is disposed at a front end of the first arm portion, the second adsorption unit is disposed at a front end of the second arm portion, the third adsorption unit is disposed in a side of the first arm portion adjacent to the base portion, and the fourth adsorption unit is disposed in a side of the second arm portion adjacent to the base portion. In the case of Example 7, the substrate is adsorbed and held in at least two adsorption units even when the substrate is warped. More particularly, in the case of Example 7, the first and second adsorption units constituting the first adsorption unit group are located at the front ends of the first and second arm portions, respectively, and the third and fourth adsorption units constituting the second adsorption unit group are located at sides of the first and second arm portions, respectively, which are adjacent to the base portion. Therefore, the substrate is adsorbed in at least one of the front ends and the sides of the first and second arm portions adjacent to the base portion. Therefore, even when the substrate is not flat with warpage, the substrate may be properly transferred by the transfer arms. In particular, when the substrate is adsorbed on the front ends of the first and second arm portions, the substrate tends to be more easily held on the transfer arm compared to a case where the substrate is adsorbed on the sides of the first and second arm portions adjacent to the base portion. Therefore, even when inertial force acts on the substrate when the transfer arm moves in an extension direction of the first and second arm portions or centrifugal force acts on the substrate when the transfer arm rotates, the substrate may be properly transferred.

Example 8: In the substrate transfer apparatus of any one of Examples 1 through 6, the at least one arm portion includes a pair of first and second arm portions extending in the same direction from the base portion. The first adsorption unit is disposed at a front end of the first arm portion, the second adsorption unit is disposed in a side of the second arm portion adjacent to the base portion, the third adsorption unit is disposed at a front end of the second arm portion, and the fourth adsorption unit is disposed in a side of the first arm portion adjacent to the base portion. In the case of Example 8, even when the substrate is warped, the substrate is held by at least two adsorption units. Therefore, even when the substrate is not flat with warpage, the substrate may be properly transferred by the transfer arm. In the case of Example 8, the first and second adsorption units constituting the first adsorption unit group are respectively located on one diagonal line of the first and second arm portions, and the third and fourth adsorption units constituting the second adsorption unit group are respectively located on another diagonal line of the first and second arm portions. Therefore, even when centrifugal force acts on the substrate during rotation of the transfer arm, the substrate may be properly transferred.

Example 9: In the substrate transfer apparatus of Example 7 or Example 8, the first suction passage is provided in one main surface side of the transfer arm, and the second suction passage includes a first portion provided in the one main surface side of the transfer arm, and a second portion in communication with the first portion through a through-hole in the transfer arm and provided in the other main surface side of the transfer arm. In this case, the first and second suction passages, which are suction passages of different systems, pass through each main surface side of the transfer arm and are fluidly independent from each other. As a result, while shortening paths of the first and second suction passages, it is possible to adsorb the substrate in the suction ports connected to the first suction passage and in the suction port connected to the second suction passage, independently.

Example 10: In the substrate transfer apparatus of Examples 1 through 6, the at least one arm portion includes a pair of first and second arm portions extending in the same direction from the base portion. The first adsorption unit is disposed at a front end of the first arm portion, the second adsorption unit is disposed in a side of the first arm portion adjacent to the base portion, the third adsorption unit is disposed at a front end of the second arm portion, and the fourth adsorption unit is disposed in a side of the second arm portion adjacent to the base portion. In the case of Example 10, the substrate is adsorbed and held in at least two adsorption units even when the substrate is warped. More particularly, in Example 10, the first and second adsorption units constituting the first adsorption unit group are located on the first arm portion, and the third and fourth adsorption units constituting the second adsorption unit group are located on the second arm portion. Therefore, even when the substrate is warped, the substrate is held by at least two adsorption units. Therefore, even when the substrate is not flat with warpage, the substrate may be properly transferred by the transfer arm.

Example 11: In the substrate transfer apparatus of any one of Examples 1 to 10, the drive unit may be configured to move the transfer arm along at least one of an X-axis extending along a horizontal direction, a Y-axis extending along the horizontal direction and orthogonal to the X-axis, a Z-axis orthogonal to both the X-axis and the Y-axis and extending along a vertical direction, and a θ-direction around the Z-axis. In this case, the substrate may be transferred in various directions by the transfer arm.

Example 12: In the substrate transfer apparatus of Example 11, the control unit may be configured to perform: controlling the drive unit to move the transfer arm along the Z-axis at a first speed, and controlling the drive unit to move the transfer arm along one of the X-axis, the Y-axis, and the θ-direction at a second speed slower than the first speed. When the substrate is transferred along the Z-axis direction (vertical direction), it is difficult to cause the misalignment of the substrate with respect to the transfer arm or dropout of the substrate from the transfer arm. Therefore, the substrate may be efficiently transferred by moving the transfer arm at a relatively fast first speed. Meanwhile, when the substrate is transferred along the X-axis direction, Y-axis direction, or θ-direction, the misalignment of the substrate with respect to the transfer arm or dropout of the substrate from the transfer arm may be relatively easily caused, due to the action of inertial force on the substrate compared to a case where the substrate is transferred along the Z-axis direction (vertical direction). In Example 12, the transfer arm is moved at a second speed, which is slower than the first speed. Therefore, the inertial force acting on the substrate is lowered, and the substrate may be properly transferred while preventing misalignment of the substrate with the transfer arm and dropout of the substrate from the transfer arm.

Example 13: Another example of a substrate transfer apparatus includes a transfer arm; a drive unit configured to move the transfer arm; and a control unit configured to control the drive unit. The transfer arm includes a base portion, at least one arm portion connected to the base portion to extend from the base portion and configured to surround an outer circumference of a substrate, a plurality of adsorption units provided in the at least one arm portion and each including a suction port that adsorbs a peripheral edge of a back surface of the substrate, and a plurality of suction passages provided in the at least one arm portion. The plurality of suction passages are respectively connected to the suction ports of the plurality of different adsorption units. In this case, the substrate is adsorbed in the suction ports of at least two of the plurality of adsorption units by suction through the plurality of suction passages. For example, even when the substrate is warped, the substrate is held in the suction ports of at least two of the adsorption units. Therefore, even when the substrate is not flat with warpage, it may be properly transferred by the transfer arm.

Example 14: The substrate transfer apparatus of Example 13 may further include a plurality of sensors each configured to detect pressure in each of the plurality of suction passages. The control unit may be configured to change a movement speed of the transfer arm by the drive unit based on results detected by the plurality of sensors. In this case, effects the same as those of the substrate transfer apparatus of Example 2 are obtained.

Example 15: In the substrate transfer apparatus of Example 14, the control unit may be configured to perform: in response to the results detected by the plurality of sensors, controlling the drive unit to move the transfer arm at a first speed when it is determined that the back surface of the substrate is adsorbed by the suction ports of three or more of the plurality of adsorption units, controlling the drive unit to move the transfer arm at a second speed slower than the first speed when it is determined that the back surface of the substrate is adsorbed by the suction ports of two of the plurality of adsorption units, and controlling the drive unit not to move the transfer arm when it is determined that the back surface of the substrate is adsorbed by the suction port of one or less of the plurality of adsorption units. In this case, effects the same as those of the substrate transfer apparatus of Example 6 are obtained.

Example 16: An example of a substrate transfer method is a substrate transfer method for transferring a substrate by a transfer arm of a substrate transfer apparatus to each of a plurality of processing modules that processes the substrate. The transfer arm includes a base portion, at least one arm portion connected to the base portion to extend from the base portion and configured to surround an outer circumference of the substrate, a plurality of adsorption units provided in the at least one arm portion, each of the plurality of adsorption units including a suction port that adsorbs a peripheral edge of a back surface of the substrate, and a plurality of suction passages provided in the at least one arm portion. The plurality of adsorption units include a first adsorption unit group including a first adsorption unit and a second adsorption unit; and a second adsorption unit group including a third adsorption unit and a fourth adsorption unit. The plurality of suction passages include a first suction passage connected to the suction ports of the first adsorption unit and the second adsorption unit, and a second suction passage connected to the suction ports of the third adsorption unit and the fourth adsorption unit. The substrate transfer method includes a first process for detecting pressure in the first suction passage by a first sensor, a second process for detecting pressure in the second suction passage by a second sensor, and a third process for changing a movement speed of the transfer arm based on results detected by the first sensor and the second sensor. In this case, effects the same as those of the substrate transfer apparatus of Examples 1 and 2 are obtained.

Example 17: In the method of Example 16, the third process may include, in response to the results detected by the first sensor and the second sensor, moving the transfer arm at a first speed when it is determined that the back surface of the substrate is adsorbed by the suction ports of the first adsorption unit group and the suction ports of the second adsorption unit group, moving the transfer arm at a second speed slower than the first speed when it is determined that the back surface of the substrate is adsorbed by the suction ports of the first adsorption unit group or the suction ports of the second adsorption unit group, and not moving the transfer arm when it is determined that the back surface of the substrate is adsorbed by one or less of the suction ports of the first adsorption unit group and the second adsorption unit group. In this case, effects the same as those of the substrate transfer apparatus of Example 6 are obtained.

According to the substrate transfer apparatus and the substrate transfer method according to the present disclosure, it is possible to transfer the substrate properly by the transfer arm even when the substrate is not flat with warpage.

From the foregoing, it will be understood that various examples of the present disclosure are described for illustrative purposes, and that various variations may be made without departing from the scope and idea of the present disclosure. Therefore, the various examples disclosed herein are not intended to limit the essential scope and ideas designated by each of the following claims.

What is claimed is:

1. A substrate transfer apparatus comprising:
a transfer arm;
a driver configured to move the transfer arm; and
a controller configured to control the driver,
wherein the transfer arm includes:
a base portion,
at least one arm portion connected to the base portion to extend from the base portion and configured to surround an outer circumference of a substrate,
a plurality of adsorbers provided in the at least one arm portion and each including a suction port that adsorbs a peripheral edge of a back surface of the substrate, and
a plurality of suction passages provided in the at least one arm portion,
wherein the plurality of adsorbers include:
a first adsorber group including a first adsorber and a second adsorber; and
a second adsorber group including a third adsorber and a fourth adsorber,
wherein the plurality of suction passages include:
a first suction passage connected to the suction ports of the first adsorber and the second adsorber, and
a second suction passage connected to the suction ports of the third adsorber and the fourth adsorber.

2. The substrate transfer apparatus according to claim 1, further comprising:
a first sensor configured to detect pressure in the first suction passage, and
a second sensor configured to detect pressure in the second suction passage,
wherein the controller is configured to change a movement speed of the transfer arm by the driver, based on results detected by the first sensor and the second sensor.

3. The substrate transfer apparatus according to claim 2, wherein the controller is configured to change the movement speed of the transfer arm by the driver, based on the results detected by the first sensor and the second sensor, and a movement direction of the transfer arm.

4. The substrate transfer apparatus according to claim 2, wherein when determined that the back surface of the substrate is adsorbed by the suction ports of the first to fourth adsorbers, from the results detected by the first sensor and the second sensor, the controller is configured to control the driver to move the transfer arm at a first speed.

5. The substrate transfer apparatus according to claim 4, wherein when determined that the pressure of one of the first suction passage and the second suction passage is higher than a threshold value set in advance, and the pressure of a remaining one of the first suction passage and the second suction passage is less than or equal to the threshold value, from the results detected by the first sensor and the second sensor, the controller is configured to control the driver to move the transfer arm at a second speed slower than the first speed.

6. The substrate transfer apparatus according to claim 2, wherein the controller is configured to perform: in response to the results detected by the first sensor and the second sensor,
controlling the driver to move the transfer arm at a first speed when determined that the back surface of the substrate is adsorbed by the suction ports of the first adsorber group and the suction ports of the second adsorber group,
controlling the driver to move the transfer arm at a second speed slower than the first speed when determined that the back surface of the substrate is adsorbed by the suction ports of the first adsorber group or the suction ports of the second adsorber group, and
controlling the driver not to move the transfer arm when determined that the back surface of the substrate is adsorbed by one or less of the suction ports of the first adsorber group and the second adsorber group.

7. The substrate transfer apparatus according to claim 1, wherein the at least one arm portion includes a pair of first and second arm portions extending in the same direction from the base portion,
the first adsorber is disposed at a front end of the first arm portion,
the second adsorber is disposed at a front end of the second arm portion,
the third adsorber is disposed in a side of the first arm portion adjacent to the base portion, and
the fourth adsorber is disposed in a side of the second arm portion adjacent to the base portion.

8. The substrate transfer apparatus according to claim 1, wherein the at least one arm portion includes a pair of first and second arm portions extending in the same direction from the base portion,
the first adsorber is disposed at a front end of the first arm portion,
the second adsorber is disposed in a side of the second arm portion adjacent to the base portion,
the third adsorber is disposed at a front end of the second arm portion, and
the fourth adsorber is disposed in a side of the first arm portion adjacent to the base portion.

9. The substrate transfer apparatus according to claim 7, wherein the first suction passage is provided in one main surface side of the transfer arm, and
the second suction passage includes:
a first portion provided in the one main surface side of the transfer arm, and
a second portion in communication with the first portion through a through-hole in the transfer arm and provided in another main surface side of the transfer arm.

10. The substrate transfer apparatus according to claim 8, wherein the first suction passage is provided in one main surface side of the transfer arm, and
the second suction passage includes:
a first portion provided in the one main surface side of the transfer arm, and
a second portion in communication with the first portion through a through-hole in the transfer arm and provided in another main surface side of the transfer arm.

11. The substrate transfer apparatus according to claim 1, wherein the at least one arm portion includes a pair of first and second arm portions extending in the same direction from the base portion,
the first adsorber is disposed at a front end of the first arm portion,
the second adsorber is disposed in a side of the first arm portion adjacent to the base portion,
the third adsorber is disposed at a front end of the second arm portion, and
the fourth adsorber is disposed in a side of the second arm portion adjacent to the base portion.

12. The substrate transfer apparatus according to claim 1, wherein the driver is configured to move the transfer arm along at least one of an X-axis extending along a horizontal direction, a Y-axis extending along the horizontal direction and orthogonal to the X-axis, a Z-axis orthogonal to both the X-axis and the Y-axis and extending along a vertical direction, and a θ-direction around the Z-axis.

13. The substrate transfer apparatus according to claim 12, wherein the controller is configured to perform:
controlling the driver to move the transfer arm along the Z-axis at a first speed, and
controlling the driver to move the transfer arm along one of the X-axis, the Y-axis, and the θ-direction at a second speed slower than the first speed.

14. A substrate transfer apparatus comprising:
a transfer arm;
a driver configured to move the transfer arm; and
a controller configured to control the driver,
wherein the transfer arm includes:
a base portion,
at least one arm portion connected to the base portion to extend from the base portion and configured to surround an outer circumference of a substrate,
a plurality of adsorbers provided in the at least one arm portion and each including a suction port that adsorbs a peripheral edge of a back surface of the substrate, and
a plurality of suction passages provided in the at least one arm portion,
wherein the plurality of suction passages are connected to the suction ports of the plurality of different adsorbers, respectively.

15. The substrate transfer apparatus according to claim 14, further comprising:
a plurality of sensors each configured to detect pressure in each of the plurality of suction passages,
wherein the controller is configured to change a movement speed of the transfer arm by the driver based on results detected by the plurality of sensors.

16. The substrate transfer apparatus according to claim 15, wherein the controller is configured to perform: in response to the results detected by the plurality of sensors,
controlling the driver to move the transfer arm at a first speed when determined that the back surface of the substrate is adsorbed by the suction ports of three or more of the plurality of adsorbers,
controlling the driver to move the transfer arm at a second speed slower than the first speed when determined that the back surface of the substrate is adsorbed by the suction ports of two of the plurality of adsorbers, and
controlling the driver not to move the transfer arm when determined that the back surface of the substrate is adsorbed by the suction port of one or less of the plurality of adsorbers.

17. A substrate transfer method comprising:
providing a substrate transfer apparatus including,
a transfer arm configured to transfer a substrate to each of a plurality of processing modules that processes the substrate,
wherein the transfer arm includes,
a base portion,
at least one arm portion connected to the base portion to extend from the base portion and configured to surround an outer circumference of the substrate,
a plurality of adsorbers provided in the at least one arm portion and each including a suction port that adsorbs a peripheral edge of a back surface of the substrate, and
a plurality of suction passages provided in the at least one arm portion,
wherein the plurality of adsorbers include,
a first adsorber group including a first adsorber and a second adsorber; and
a second adsorber group including a third adsorber and a fourth adsorber,
wherein the plurality of suction passages include,
a first suction passage connected to the suction ports of the first adsorber and the second adsorber, and
a second suction passage connected to the suction ports of the third adsorber and the fourth adsorber;
detecting pressure in the first suction passage by a first sensor;
detecting pressure in the second suction passage by a second sensor; and
changing a movement speed of the transfer arm based on results detected by the first sensor and the second sensor.

18. The substrate transfer method according to claim 17, wherein the changing includes, in response to the results detected by the first sensor and the second sensor,
moving the transfer arm at a first speed when determined that the back surface of the substrate is adsorbed by the suction ports of the first adsorber group and the suction ports of the second adsorber group,
moving the transfer arm at a second speed slower than the first speed when determined that the back surface of the substrate is adsorbed by the suction ports of the first adsorber group or the suction ports of the second adsorber group, and
not moving the transfer arm when determined that the back surface of the substrate is adsorbed by one or less of the suction ports of the first adsorber group and the second adsorber group.
